(19) United States
(12) Patent Application Publication
(10) Pub. No.: US 2003/0058908 A1
(43) Pub. Date: Mar. 27, 2003

(54) Vertically coupled ring resonators and laser structures

(76) Inventor: Giora Griffel, Tenafly, NJ (US)

Correspondence Address: Duane Morris LLP, Suite 100, 100 College Road West, Princeton, NJ, 08540, US

(21) Appl. No.: 10/193,432

(22) Filed: Jul. 11, 2002

Related U.S. Application Data
(60) Provisional application No. 60/304,799, filed on Jul. 11, 2001.

(51) Int. Cl. H01S 5/00; H01S 3/083

(52) U.S. Cl. 372/43; 372/94

(57) ABSTRACT

A vertically-coupled ring resonator structures are disclosed. In one embodiment, the structure comprises a base layer having at least one or two channels wherein a top surface of the base layer is grown planarized with regard to a top surface of each the said channels and a ring resonator coupled to the base layer top surface vertically displaced from and in optical communication with the channels is operable to transfer at least one wavelength of the light between said channels. In another embodiment of the invention, a vertically-coupled ring resonator semiconductor laser is formed using a vertically-coupled ring configuration. The laser comprises a base layer having two channels operable to generate light wherein a top surface of the base layer is planarized grown with regard to a top surface of each of said channels, a first reflecting surface associated with each of the channels operable to substantially contain light within the associated channel, and a ring resonator coupled to said base layer top surface vertically displaced from and in optical communication with the channels operable to transfer at least one wavelength of the light the channels, wherein the first reflecting surface and the ring resonator define a lasing cavity. In another embodiment of the invention, two ring resonators are employed as reflecting surfaces to create a laser cavity.

### RELATED APPLICATIONS

This application is related to U.S. Provisional Patent Application serial No. ______, entitled “Three Dimensional Photonics Integration, having a filing date of ______, 2002, which is incorporated by reference herein.

### CLAIM OF PRIORITY

This application claims the benefit, pursuant to 35 U.S.C. 119, of U.S. Provisional Patent Application serial No. 60/304,799, entitled, “Vertically Coupled Ring Resonators and Laser Structures,” having a filing date of Jul. 11, 2001, which is incorporated by reference herein.

### FIELD OF THE INVENTION

This application relates to integrated optical circuits and more specifically to vertically coupled ring resonators and their use in semiconductor lasers.

### BACKGROUND

There is an ever-increasing demand for denser photonic integrated circuits (PIC). Of particular interest is the fabrication of PIC, such as those comprising waveguides for generating, guiding, and processing electromagnetic energy, such as laser light. Of particular interest are applications involving close loop waveguiding structures known in the art as ring resonators. These structures are characterized by their capability to support a specific set of resonance frequencies, much like their linear counterpart, the Fabry-Perot (FP) resonators. The resonance-supporting characteristic is a key enabling element in a wide variety of applications including optical filters, lasers, and cavity-enhanced modulators. An integral part of the structure utilizing ring resonators is the optical coupling region in which light traveling in a system through an interconnecting optical waveguide is brought to a close proximity with the ring resonator and coupled into it. In addition, a second coupling region may be provided to couple light out of the ring resonator and guide it further to the next part of the optical system. Two configurations of light coupling between optical waveguides are known in the art: planar and vertical. Planar coupling occurs when two waveguides, which are laterally displaced from each other, are brought into close enough proximity that light may be coupled from one waveguide to the other. This process is limited by the resolution accuracy of the lithographic process involved in fabricating the lateral coupling structure. It is also limited in that the two waveguides are comprised of the same layered structure and therefore exhibit the same properties and functionality. Therefore, to integrate sections of different functionality would require the use of elaborated molecular growth techniques, such as Selective Epitaxy or fine etch and regrowth of regions with different properties on the same substrate.

The second coupling technique, known as vertical coupling, has been used to construct tunable lasers and for coupling buried interconnect channels to circular resonance structures. However, a problem that arises when fabricating this kind of structure is that the lateral boundaries between the core and the cladding of the lower waveguide induce undulations that propagate vertically in the layers above it. These undulations cause significant loss of light propagating into a second waveguide crossing over. In particular, the loss associated with waveguide crossing over an undulated surface is detrimental to the proper operation of ring resonators, as light circulating in the ring crosses over the undulated region many times. Ring resonator properties are characterized by a quality factor of the resonator that determines how long light coupled into the ring can circulate in the ring before it dies out. This property is associated with the “photon lifetime” and is directly related to the sharpness of the resonance lines supported by the ring. To avoid loss resulting from surface undulations, the waveguide cores must either be co-linear without crossing, which prohibits the construction of high quality ring resonators and results in very limited use, or vertically coupled in rather complicated and costly techniques such as wafer bonding.

In wafer-bonded structures the various layers of a device are fabricated onto a plurality of wafers and then the processed wafers are bonded, or fused, together and thinned down to form a final product. A number of bonding and fusion techniques are known, such as fusion bonding, anodic bonding, and adhesive bonding. Fusion bonding is a direct bonding process wherein two clean, flat surfaces are covalently bonded through the application of pressure and heat. Anodic bonding involves bonding surfaces through the application of strong electric fields and heat. Adhesive bonding is applicable to the widest range of wafer materials, but the bond strengths achieved are typically lower than those for either fusion or anodic bonding.

Bonding and fusion techniques suffer many disadvantages. Typically, wafer bonding requires accurate alignment of the components of a first wafer with respect to the components of a second wafer and then holding the wafers in fixed relation for the bonding process. Current methods for aligning wafers prior to bonding are time-consuming and require expensive equipment. Also, due to the fragile nature of the wafers, mechanical support must be provided to prevent the wafers being bonding from breaking. This is of particular interest for materials such as Gallium Arsenide (GaAs), and Indium Phosphide (InP). Thus, wafer breakage during device manufacturing is another disadvantage associated with bonding and fusion. Furthermore, the process of bonding and fusing wafers does not typically provide the precise and small, vertical dimensions between layers necessary for modern photonic and electronic integrated circuits.

Another technique for achieving vertical integration includes growing layers utilizing metal organic chemical vapor deposition (MOCVD). For example, the active region (e.g., waveguide) of a photonic circuit may be defined as a mesa structure, and a semi-insulating current-blocking layer (e.g., cladding layer) may be grown around sidewalls of the mesa structure utilizing MOCVD. One disadvantage of this technique is the formation of surface irregularities, such as “rabbit ears” above the boundary of the etched mesa. During the growth of the cladding layers by MOCVD, growth near edges of masking layers advances more quickly than in the bulk of the cladding layer. This results in wall-like structural defects that are referred to as “rabbit ears.” These rabbit ears tend to produce a non-uniform, non-planar surface, which must be planarized in order to achieve vertical integration. Planarization often involves grinding, polishing, and/or buffing the surface. This can be time consuming, wasteful, and expensive.

A means of overcoming the described obstacles for efficient coupling is disclosed in related U.S. patent application, Ser. No. ______, entitled “Three-Dimensional Photonic Integration, which is incorporated by reference herein. This method facilitates placing a crossing element or device above a buried one in a proximity that is sufficiently close for efficient optical coupling. The closer the planarized layer is to the buried waveguide core, the closer it would be possible to place the core of the upper waveguide which, in turn, would result in highly efficient coupling over a short distance.

It is possible to provide a unique configuration for constructing structures having ring resonators fabricated vertically and in a close proximity to a buried waveguide core where an intermediate layer between the ring resonator and the buried waveguide is planarized.

### BRIEF DESCRIPTION OF THE DRAWINGS

The above and other advantages and features of the present invention will be better understood from the following detailed description of the preferred embodiments of the invention, which is provided in connection with the accompanying drawings. The various features of the drawings may not be to scale. Included in the drawings are the following figures:

FIG. 1 illustrates a perspective view of a vertically-coupled ring resonator in accordance with an embodiment of the present invention;

FIG. 2 illustrates a cross sectional view of the vertically-coupled ring resonator depicted in FIG. 1;

FIG. 3a illustrates a top view of laser structure having a ring resonator as an intracavity selective filter in accordance with the principles of the invention;

FIG. 3b illustrates a top view of a second laser structure having two ring resonators serving as front and back frequency selective reflection elements in accordance with the principles of the invention;

FIG. 4 illustrates a perspective view a vertically-coupled ring resonator constructed of a plurality of vertically stacked ring resonators in accordance with the principles of the invention;

FIG. 5 illustrates a perspective view of another embodiment of a longitudinal array of vertically-coupled ring resonators in accordance with the principles of the invention; and

FIG. 6 illustrates a top-view of an exemplary embodiment of a co-directional frequency selective element consisting of two serially connected and vertically coupled ring resonators in accordance with the principles of the invention.

### DETAILED DESCRIPTION

It is widely understood that a means to reduce bending and scattering loss in a bent optical waveguide is provided by creating the largest possible lateral index step between the core and the lateral cladding of the waveguide. This has been demonstrated for the guiding channel of a ring resonator (RR) structure or a racetrack resonator (RTR) and its surrounding by having these resonators deeply etched well below the core layer of the waveguide. Furthermore, this deep etching achieves an extremely small diameter (<10 μm) of the ring resonators. However, due to the tight confinement of the optical mode guided by such large index-step waveguides, it is necessary to have a very small air gap between the RR/RTR and the interconnect channels coupling light into and out of the resonator. To overcome this restraint a structure providing vertical coupling from buried interconnected waveguiding channels to a deeply etched ring resonator placed in close proximity to the buried interconnect channels is necessary.

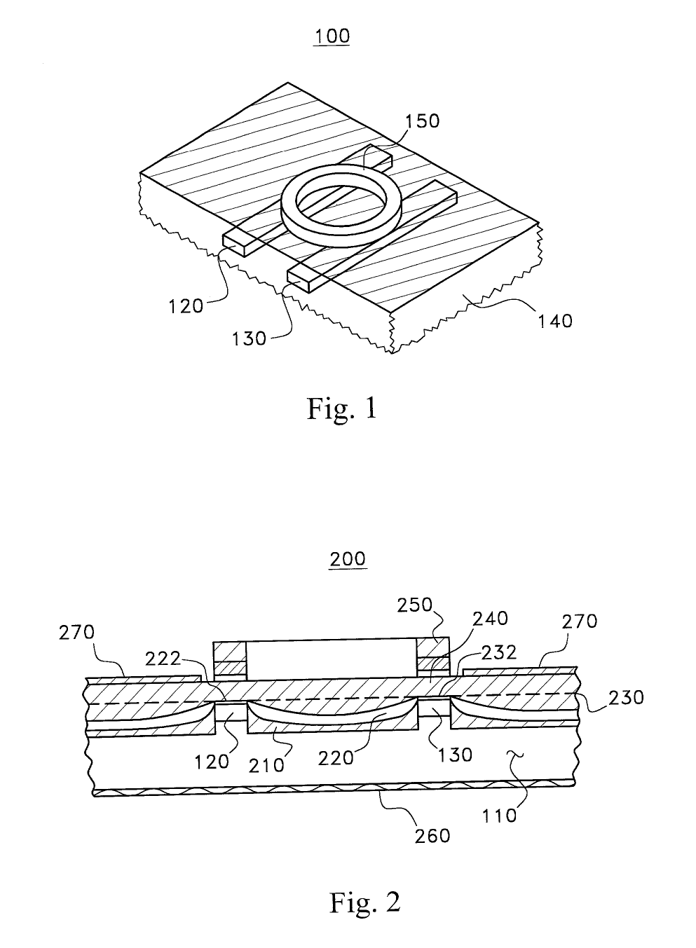

FIG. 1 illustrates a perspective view of a vertically-coupled ring resonator tunable laser 100 in accordance with the principles of the invention. As shown, the input channel 120 and output channel 130 are buried below the surface 140 of base layer or substrate 110 while the ring resonator 150 is fabricated substantially on surface 140 and in close vertical proximity to channels 120, 130.

FIG. 2 illustrates a cross-sectional view 200 of the vertically coupled ring resonator laser shown in FIG. 1. In this illustrative embodiment, buried input channel 120 and output channels 130 are formed within n-type substrate 110 by the steps of first etching their mesas, followed by a regrowth of alternating current blocking layers 210 and 220, planarization of an intermediate p-type cladding layer 230, growth of the upper guiding layer 240 of the ring and its top cladding 250.

The wafer is then etched below the upper guiding layer 240 and above the lower guiding layer 230 of the buried channels to form the ring. Electrodes 260, 270 are next formed on the bottom and top surfaces, respectively, of the structure to enable control of the refractive index, gain and loss at the transition between the p-type and n-type regions of the channels and/or within the input channel 120 and output channel 130.

In one aspect of the invention, to facilitate transfer of electrical charge through the p-n junction, quantum wells 222, 232, (QW) are formed within channels 120, 130, respectively. The formed p-n junction alternatively, or in addition, may be formed close to or within the top (ring) guiding layer 240 so as to make the ring active with an electrode layer formed on the top of the ring to control the gain or loss properties of the ring.

In this illustrated embodiment coupling into and out of the ring is performed vertically. There is no air gap and this is advantageous as there is fine control of the spacing between the top and the bottom waveguides resulting from the epitaxial technique for growing each of the layers.

The ring is etched down in base layer 110 to obtain a relatively large index step and, as a consequence, a High-Q resonator. Such a structure provides very little perturbation in the symmetry of the ring and therefore little loss due to mode matching in the coupling region. Coupling into and out of the ring is electrically controlled by introducing the p-n, or enhanced, junction. In another aspect of the invention, the ring geometry can be replaced by a racetrack for enhancement of the coupling and/or variation in the transmission spectra of the ring.

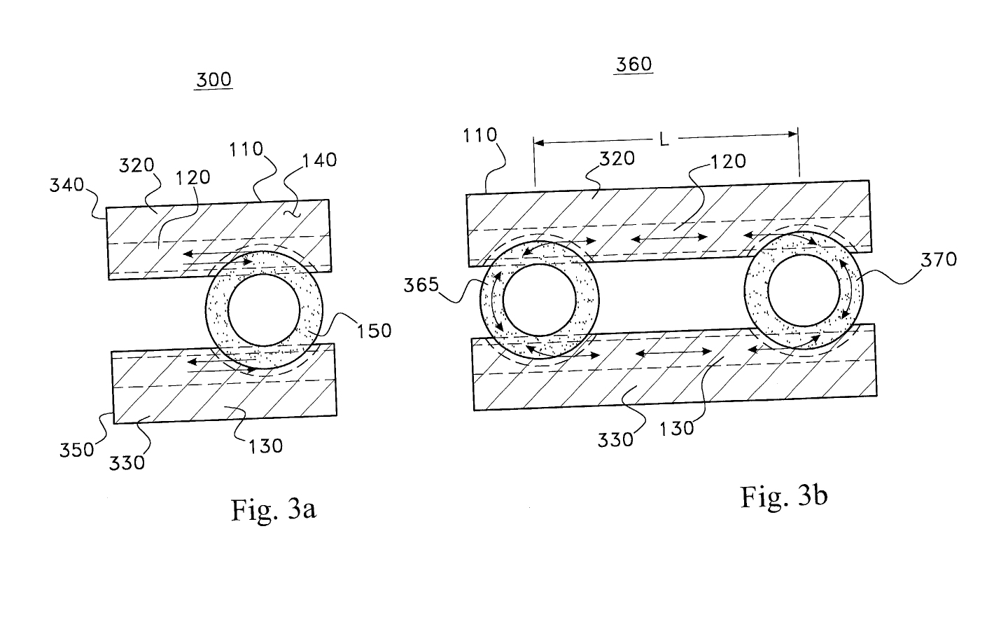

FIG. 3a illustrates one embodiment of a vertically coupled ring resonator semiconductor laser 300 in accordance with the principles of the invention. In this illustrative embodiment, laser 300 is comprised of two straight channels 120, 130, buried in substrate 110 and coupled vertically to upper ring resonator 150. Gain is provided by pumping current to the straight channels 120, 130 by the electrodes 320, 330, respectively, shown in the hatched area. A laser cavity is defined by the cleaved facets 340, 350, on, in this case, the left side of gain material. Light propagates back and forth between the facet 340 of the upper channel 120 and the facet 350 of the lower channel 350, through ring 150, as shown by the arrows.

FIG. 3b illustrates another embodiment of a semiconductor laser 360 using two vertically-coupled ring resonators as the reflective surfaces. In this exemplary embodiment, the laser cavity is defined by two ring resonators 365, 370, which act as the right and the left mirrors of the laser cavity. In this case, light propagates in the two channels and the two ring resonators as indicated by the arrows. The straight segments of the cavity, i.e. the buried channels, are manufactured with active region providing gain to the light propagating through them. The two rings allow predetermined, selected or a desired resonance frequency, or narrow-band of frequencies, to couple through them from one channel to the other. Gain is again provided by the medium of the buried channels to overcome transmission and propagation loss in the cavity. When the gain is sufficient to overcome transmission and propagation losses, the lasing action occurs as is understood in the art. The spectral characteristics of the lasers in FIGS. 3a and 3b may be determined by the spacing, L, and dimensions of the ring resonator(s).

In another aspect, which is not shown, each ring resonator may be replaced by a racetrack resonator or any other shape of closed loop resonators, or by a series of ring or racetrack resonators.

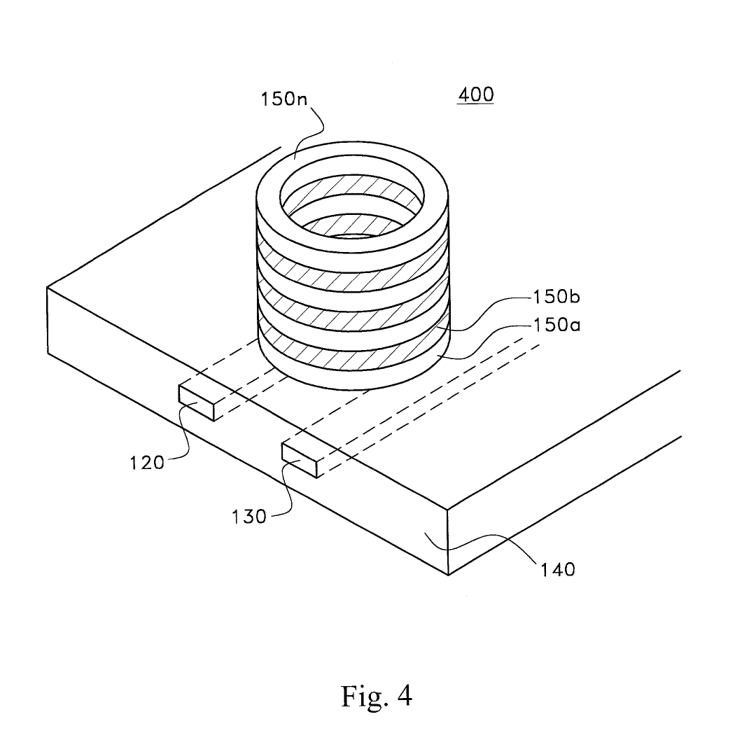

FIG. 4 illustrates another aspect of a semiconductor ring resonator laser wherein a plurality of ring resonators, represented as 150a, 150b, 150n, are vertically stacked with respect to each other. This configuration is advantageous as it provides a plurality of vertical modes, causing splitting of the resonance of each ring and, as a result, broadband transmission of a plurality of wavelengths through the rings

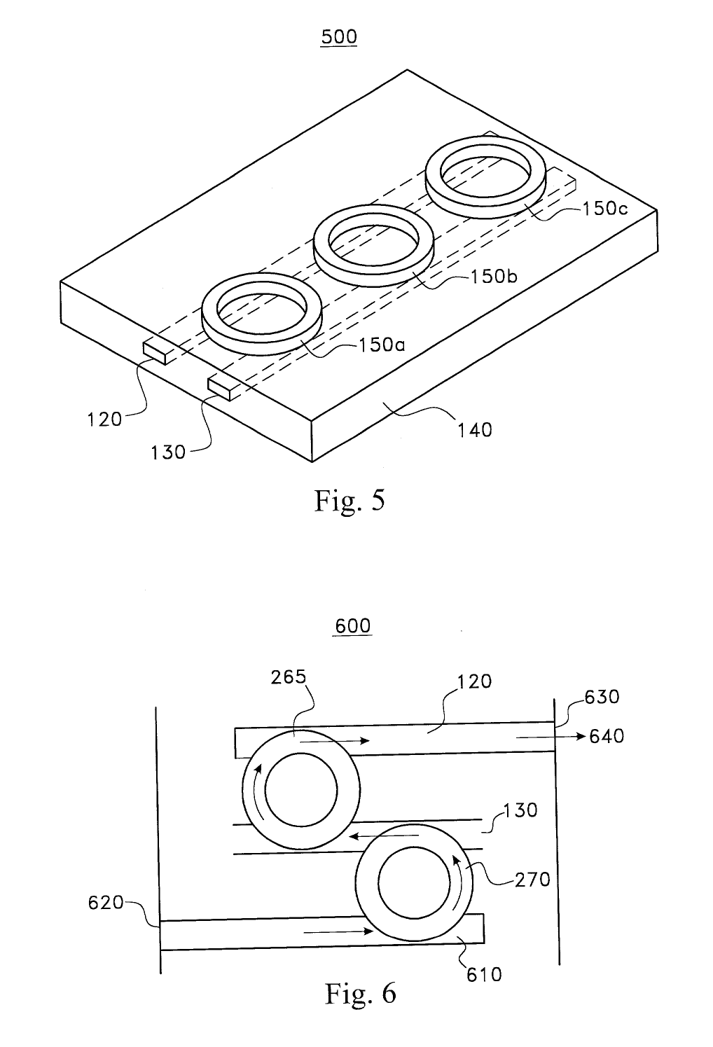

FIG. 5 illustrates still another aspect of a semiconductor ring resonator laser wherein a longitudinal array of ring resonators are each in vertical communication with buried channels 120, 130. This configuration is advantageous as the concerted effect of longitudinal stacking of rings at the appropriate spacing results in the broadening of the resonance modes of the individual rings.

FIG. 6 illustrates a top view of another embodiment of a vertically-coupled ring resonator laser 600 wherein the ring resonators may be serially placed with respect to the waveguides 120, 130, and 610 such that co-directional coupling of light is achieved as light is coupled from waveguide 610 to ring 270, to waveguide 130, to ring 265, to waveguide 120. In this case, facet edges 620, 630 may define a laser cavity in which light is contained. When sufficient gain is achieved to overcome propagation and coupling losses, a lasing light 640 exits from the gain medium at facet edge 630, for example. Since light has to couple through both rings, which might have different dimensions, only frequencies that fulfill resonance conditions of both rings are allowed to continue. This can be advantageously utilized to facilitate lasing at single frequency and tuning.

It will be further understood that the ring/racetrack resonators of other configurations containing two rings such as, for example, FIG. 3b, can be made differently such that coupling through both the resonators 365, 370 occurs substantially simultaneously only at one frequency or within a narrowband in a gain spectrum. Thus the laser operates in a single mode. Forming a junction near the ring/racetrack waveguide and applying a voltage signal to the ring resonators to vary their refractive indices can achieve tuning the operating frequency.

While there has been shown, described, and pointed out, fundamental novel features of the present invention, it will be understood that various omissions and substitutions and changes in the apparatus described, in the form and details of the devices disclosed, and in their operation, may be made by those skilled in the art without departing from the spirit of the present. For example, wavelength selective filter may be fabricated using a ring resonator vertically-coupled to at least one embedded channel. Furthermore, although the present invention has be described with regard to the terminology “vertical-coupling,” it would be understood in the art that the device would operate with different orientations of the structures disclosed. Accordingly, it is fully intended and contemplated that structures oriented 90 degrees to those illustrated are within the scope of the invention. It is further expressly intended that all combinations of those elements which perform substantially the same function in substantially the same way to achieve the same results are within the scope of the invention. Substitutions of elements from one described embodiment to another are also fully intended and contemplated.

What is claimed is:

1. A semiconductor laser comprising:
a base layer having two channels operable to generate and propagate light therein;
a blocking material grown on said base layer, said blocking material having a surface grown planarized with regard to a top surface of each of said channels;
a first reflecting surface associated with each of said channels operable to substantially contain said light within said channel; and
a ring resonator coupled to said blocking material surface vertically displaced from and in optical communication with said channels operable to transfer at least one wavelength of said light between said channels, wherein said first reflecting surface and said ring resonator define a lasing cavity.

2. The semiconductor laser as recited in claim 1, wherein at least one of said first reflecting surfaces is highly-reflective.

3. The semiconductor laser as recited in claim 2, wherein said highly-reflective surface is a facet of said channel.

4. The semiconductor laser as recited in claim 1, wherein at least one of said first reflecting surfaces is partially-reflective.

5. The semiconductor laser as recited in claim 1, wherein said partially reflective surface is a facet of said channel.

6. The semiconductor laser as recited in claim 1, wherein said first reflective surface is a second ring resonator coupled to said surface vertically displaced from and in optical communication with said channels operable to transfer at least one wavelength of said light between said channels.

7. The semiconductor laser as recited in claim 1, wherein said ring resonator further comprises a plurality of ring resonators, each of said ring resonators operable to transfer at least one wavelength of said light between said channels.

8. The semiconductor laser as recited in claim 6, wherein said second ring resonator further comprises a plurality of ring resonators, each of said ring resonators operable to transfer at least one wavelength of said light between said channels.

9. The semiconductor laser as recited in claim 7, wherein each of said plurality of ring resonators are in communication with said channels.

10. The semiconductor laser as recited in claim 7, wherein said plurality of ring resonators are vertically coupled together.

11. The semiconductor laser as recited in 1, wherein said cavity is determined based on a distance between said first reflective surfaces and said ring resonator and a size of said ring resonator.

12. The semiconductor laser as recited in claim 1, further comprising:
a third channel; and
a ring resonator coupled to said surface vertically displaced from operable to transfer at least one wavelength of said light between a selected one of said two channels and said third channel.

13. The semiconductor laser as recited in claim 1, wherein said channel includes a gain medium.

14. The semiconductor laser as recited in claim 1, wherein said ring resonator includes a gain medium.

15. The semiconductor laser as recited in claim 6, wherein said second ring resonator includes a gain medium.

16. A semiconductor vertically coupled ring resonator structure comprising:
a base layer having at least one channel operable to generate and propagate light therein;
a blocking material grown on said base layer, said blocking material having a surface grown planarized with regard to a top surface of each of said at least one channel; and
a ring resonator coupled to said blocking material surface vertically displaced from and in optical communication with at least one of said channels operable to isolate at least one wavelength of said light.

17. The structure as recited in claim 16, wherein said channel includes a gain medium.

18. The structure as recited in claim 16, wherein said ring resonator includes a gain medium.

19. The structure as recited in claim 16, wherein said channel includes a medium capable of changing a refractive index.

20. The structure as recited in claim 16, wherein said ring resonator includes a medium capable of changing a refractive index.
